(19) United States
(12) Patent Application Publication
(10) Pub. No.: US 2005/0263817 A1
(43) Pub. Date: Dec. 1, 2005

(54) Transistor comprising fill areas in the source drain and/or drain region

(76) Inventors: Martin Wendel, Hohenbrunn (DE); Martin Streibl, Petershausen (DE); Kai Esmark, Neuried (DE); Philipp Riess, Munchen (DE); Thomas Schafbauer, Paris (FR)

Correspondence Address: BRINKS HOFER GILSON & LIONE, P.O. BOX 10395, CHICAGO, IL, 60610, US

(21) Appl. No.: 11/138,918

(22) Filed: May 26, 2005

Related U.S. Application Data
(63) Continuation of application No. PCT/DE03/03914, filed on Nov. 26, 2003.

(30) Foreign Application Priority Data
Nov. 27, 2002 (DE) DE 102 55 359.9

(51) Int. Cl. H01L 29/76

(52) U.S. Cl. 257/328

(57) ABSTRACT

A transistor contains a source region and a drain region. Two or more fill areas are formed such that the fill areas and the source and/or drain region engage in one another. The fill areas have vertical dimensions which are at least of equal size to the vertical dimensions of the source and/or of the drain region. The fill areas and the source and/or drain region extend at least partially over a common vertical section. The fill areas are formed from an oxide and/or a nitride.

### PRIORITY

This application is a continuation of International Application PCT/DE03/03914, filed on Nov. 26, 2003, which claims the benefit of priority to German Patent Application 102 55 359.9, filed on Nov. 27, 2002, incorporated herein by reference

### TECHNICAL FIELD

The present invention relates to a transistor and in particular to a transistor that has fill areas which are arranged in the source and/or drain region.

### BACKGROUND

Scale effects are occurring increasingly in modern technologies for production of semiconductor components and integrated circuits. Technology parameters such as layer resistances have undesirable relationships with the structure sizes of the respectively used technology. One example of this is metal surfaces, with which problems occur when specific surfaces sizes are reached during chemical/mechanical polishing (CMP). In more recent technologies, this problem has been solved by the introduction of regular fill structures in some mask levels, which are intended to homogenize the density of, for example, a metal level or a polysilicon level over the wafer.

As has been observed in component simulations and experiments, the threshold voltage of a transistor (the voltage at which the transistor starts to conduct current) depends on the size of its diffusion region. This results in a considerable scatter in the threshold voltage and in other characteristic variables of a transistor on the chip, depending on the size, the geometry and the environment of the transistors formed on a chip. Considerable problems result during circuit simulation and during the subsequent circuit matching. This relates in particular to driver transistors, which require a large transistor width owing to their high output power. The effect is even further exacerbated in the case of transistors which are connected directly to input or output connections of the integrated circuit and are thus particularly at risk in the event of electrostatic discharges (ESD transistors). These ESD transistors require diffusion regions to have a minimum size as a protective measure, which results in the diffusion regions having a relatively large width and height, so that these ESD transistors are particular severely affected by the characteristic shift.

German Patent Specification DE 100 54 184 C1 discloses an ESD transistor in which isolation areas, in the form of strips, are embedded in the diffusion regions of the transistor in order to improve its ESD resistance and its driver capability, which is not adversely affected at the same time. The areas in the form of strips in this case have a vertical extent which is less than the vertical extent of the source and/or drain region of the transistor. These isolation areas in the form of strips are arranged parallel to one another and separated from one another, and are formed at right angles to the gate area. This avoids the current being constricted in the area of the diffusion region, and the reduction in the effective area available for carrying current means that the desired effect results in an increase in the diffusion resistance. The structure in the form of strips can also be transferred into a salicide layer which is formed on the diffusion regions. While maintaining the driver capability of the transistor, the isolation areas in the form of strips end at a specific distance in front of the channel region of the transistor. One disadvantage of this structure is that only the ESD resistance can be improved. It is thus impossible to deliberately avoid characteristic shifts of the transistors, in particular the shifting of the threshold voltage, resulting from the effects explained initially.

Furthermore, U.S. Pat. No. 5,721,439 discloses a transistor in which areas in the form of strips are formed parallel to the gate area of the transistor in order to improve the ESD resistance. The areas in the form of strips are offset with respect to one another in their longitudinal direction. The areas in the form of strips have an oxide area and a polysilicon area which is formed on it, and are formed only on the substrate surface. The diffusion regions of the transistors extend between the areas in the form of strips within the substrate. No further areas, for example as isolation areas, are formed in the diffusion regions. It is thus not possible to prevent the characteristic of the transistors from being shifted as a result of the effects described initially.

Furthermore, a transistor shown in U.S. Pat. No. 6,153,909 has isolation areas arranged within the diffusion regions of the transistor in order to avoid hot carrier effects. The isolation areas are embedded in the form of boxes only in the diffusion region and have vertically smaller dimensions than the diffusion regions. In order to reduce the hot carrier effect, the isolation areas are formed at least partially underneath spacer areas or underneath the gate area. Once again, this transistor design does not allow characteristic shifts to be deliberately avoided.

### BRIEF SUMMARY

By way of introduction only, in one embodiment a transistor has a source region and a drain region, both of which are formed in a substrate. The transistor has two or more fill areas, with each fill area being arranged at least partially in the substrate and comprising an oxide and/or a nitride. The fill areas and the source and/or drain region extend into one another. The fill areas have vertical dimensions which are at least of equal size to the vertical dimensions of the source and/or drain region. This makes it possible to produce a transistor in which it is possible to reduce or prevent any shift in the characteristic variables and, in particular, a characteristic shift, in particular a shift in its threshold voltage, irrespective of its size, its geometry or its environment, in which the transistor is formed, for example, in an integrated circuit. In general, this allows any desired transistor that is formed on an integrated circuit to be designed to correspond to the transistor according to the invention. This makes it possible to effectively limit any scatter of the transistor characteristic variables, in particular of the threshold voltage, so that the simulation of circuits or the matching of circuits to one another can be carried out considerably more accurately, more easily and in an optimized manner.

In one embodiment, the fill areas are arranged such that they pass completely through the source and/or drain region in the vertical direction. Since the fill areas pass through the source and/or drain region in the vertical direction this makes it possible to prevent a shift in the characteristic variables of the transistor in a particularly effective and efficient manner.

The fill areas may be integral and essentially homogenous. Also, the fill areas and the source and/or drain region form a substantially planar surface in the surface in the substrate. Starting from this planar surface, it is possible to provide for the fill areas to have a depth which is greater than the depth of the source and/or drain region. Considered from the substrate, the fill areas are therefore closer to the substrate than the source and/or drain region are/is to the substrate.

In addition, each of the fill areas may comprise at least two pieces which, in particular, are arranged one above the other in the vertical direction. In this case, it is possible to provide a first piece of a fill area to in each case be formed integrally and essentially homogenously, and to form a substantially planar surface with the source and/or drain region on the surface facing away from the substrate. It is also possible to provide for this first piece of each fill area to extend over this surface facing away from the substrate. This first piece can also be designed such that it does not extend as far as this surface. It is also possible to provide for this first piece of each fill area to be formed at a distance from the substrate which is shorter than the distance between the source and/or drain region and the substrate. However, it is likewise also possible to provide for this distance between the first piece of a fill area and the substrate to be larger than the distance between the source and/or drain region and the substrate. The first piece of a fill area which is composed of at least two pieces can thus be produced in many ways. The first piece can thus be formed as an upper end piece or a lower end piece of an assembled fill area, as well as between a second and a third piece of an assembled fill area. The first piece considered in its own right can thus have vertical dimensions which are less than, equal to or greater than the vertical dimensions of the source and/or drain region.

It is possible to provide for at least one second piece of a respective fill area to be coincident with the first piece and, considered in the vertical direction, to be arranged on or underneath this first piece. Depending on the technology which is used for production of the components in an integrated circuit, this makes it possible to achieve an additional improvement with respect to any possible shift of the characteristics of the transistor. It is particularly advantageous for the fill areas to be slightly electrically conductive at least in subareas, or to be electrically insulating at least in subareas, in comparison to the source and/or drain region. In this case, it is possible for the entire fill area to be either slightly electrically conductive or to be electrically insulating. However, it is also possible to provide for a fill area which is assembled from two or more pieces to have at least one piece which is slightly electrically conductive and at least one second piece which is electrically insulating.

The fill areas or pieces of the fill areas may be in the form of well areas which have a relatively high resistance. The source and/or drain region is in this case embedded in the well area, with the well area being formed in the substrate, and the fill areas being subareas of the well areas. It is also possible to provide for the slightly electrically conductive pieces of a fill area to be formed, in particular, from polysilicon. It may be possible to provide for the fill areas to be formed completely from well areas. It is also possible to provide for each fill area to have a first piece which is formed by a well area, and a second piece which is composed of an electrically insulating material. Furthermore, it is possible to provide for each fill area to have a third piece which is composed of polysilicon and is arranged directly on the first piece or the second piece. In this case as well, each individual piece of fill area may have vertical dimensions which are smaller than the vertical dimensions of the source and/or drain region. The fill areas can thus be formed integrally or from two or more pieces in many ways, as well as being completely electrically insulating or completely slightly electrically conductive, or being completely electrically insulating in subareas, and slightly electrically conductive in subareas.

In one embodiment, the fill areas are essentially strips which are arranged parallel to one another and are arranged at right angles to the gate area in particular on that plane on which this gate area of the transistor extends. However, it is also possible to provide for the fill areas to be solid cylinders, hollow cylinders or polygonal pillars. The geometric configuration of the fill areas is not restricted by the specific embodiments mentioned, but can be configured geometrically in many ways. However, the significant factor is that the fill areas are—designed and arranged in such a way as to prevent any shift in the characteristic variables or characteristics, in particular in the threshold voltage, of the transistor.

It is also possible to provide for a salicide layer to be formed on the source and/or drain region and/or on the fill areas. It is also possible for the structure of the fill areas to be formed in this salicide layer.

The foregoing summary has been provided only by way of introduction. Nothing in this section should be taken as a limitation on the following claims, which define the scope of the invention.

### BRIEF DESCRIPTION OF THE DRAWINGS

The following text explains in more detail a number of embodiments of the invention, using schematic drawings, in which:

FIG. 1 shows a plan view of a first embodiment for the transistor;

FIG. 2 shows a section illustration of a first embodiment of the transistor;

FIG. 3 shows a section illustration of a second embodiment of a transistor;

FIG. 4 shows a section illustration of a third embodiment of a transistor;

FIG. 5 shows a view of a fourth embodiment of a transistor;

FIG. 6 shows another plan view of a fifth embodiment of a transistor; and

FIG. 7 shows a section illustration of a sixth embodiment of a transistor.

Identical or functionally identical elements are provided with the same reference symbols in the figures.

### DETAILED DESCRIPTION OF THE PREFERRED EMBODIMENTS

FIG. 1 shows a plan view of a transistor. The transistor has a drain region D and a source region SO. An elongated gate area G extends between the two diffusion regions D and SO. Fill areas FB which are in the form of strips are formed in the drain region D, are arranged parallel and essentially at equal intervals from one another, and are arranged at right angles to the gate area G on the plane on which this gate area G extends. These fill areas are arranged in an analogous manner in the source region SO. The fill areas FB in this embodiment are arranged such that they pass virtually completely through the respective diffusion region in which they are formed, and are at a distance from the gate area G.

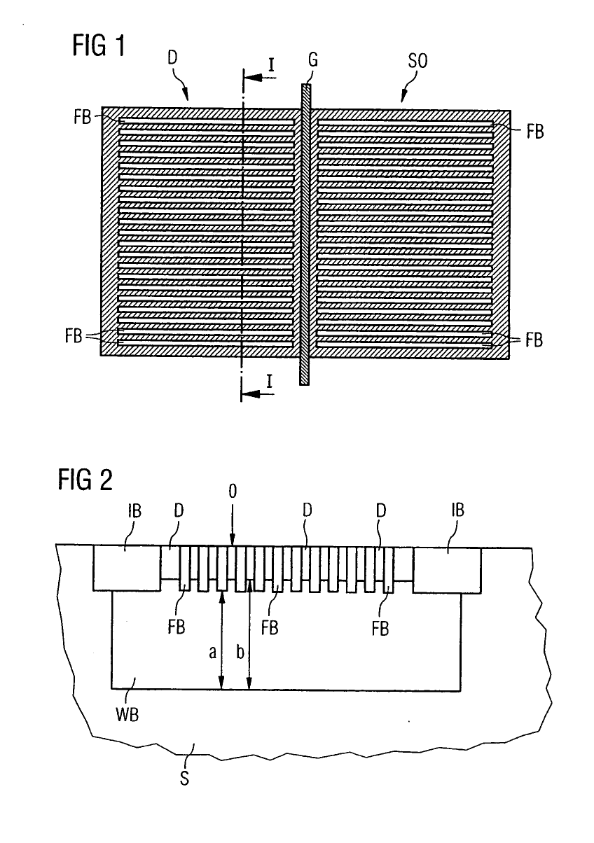

FIG. 2 shows a section illustration of the first embodiment. FIG. 2 shows a section along the line II (FIG. 1). FIG. 2 illustrates isolation areas IB which allow the drain and/or source regions D and SO to be isolated from adjacent diffusion regions of adjacent transistors, which are not shown in FIG. 1. The number of fill areas FB in FIG. 2 is less than the number of fill areas FB in FIG. 1 for convenience. The drain region D in the section illustration of the first embodiment of the transistor shown in FIG. 2 is formed in a well area WB. The well area WB is formed in a substrate S. The fill areas FB, which are in the form of strips, are arranged at equal intervals from one another in the horizontal direction. In the first embodiment, these fill areas FB are integral and are produced as strips composed of silicon dioxide. The fill areas FB on the side facing away from the substrate S form an essentially planar surface O with the drain diffusion region D. Starting from this planar surface area, the fill areas FB extend to a depth which is greater than the depth to which the drain diffusion region D extends, starting from this planar surface O. The fill areas FB thus pass completely through the drain region D and have vertical dimensions which are larger than the vertical dimensions of the drain region D. The distance a between the fill areas FB and the substrate surface, which in this case is produced by the transition between the well area WB (well base) and the substrate S, is less than the distance b between the lower area of the drain region D and this substrate surface. However, it is also possible to provide for the integral fill areas FB to be arranged such that they are further away from the substrate surface and from the base of the well area WB than the lower areas of the drain diffusion region D. It is also possible to provide for the fill areas FB to pass completely through the drain region D, and for the fill areas FB and the drain region D to be at the same distance from the base area of the well area WB. It is likewise possible to provide for the fill area FB to extend beyond the surface O.

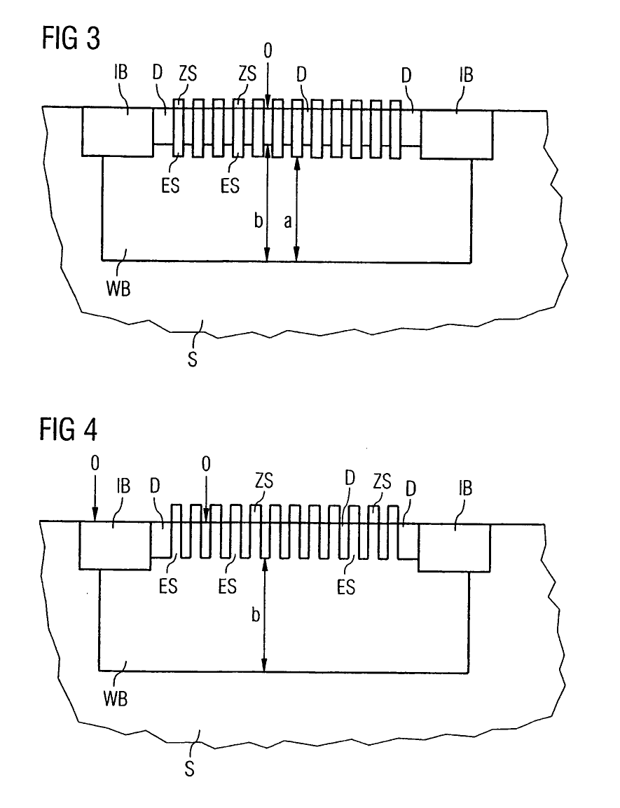

A second embodiment of the transistor is shown in the section illustration in FIG. 3. In this embodiment, the fill areas FB are formed from two pieces. The first pieces ES of each fill area are formed in a corresponding manner to the fill areas FB shown in FIG. 2. In addition, each fill area FB in FIG. 3 has a second piece ZS, which are arranged in the vertical direction on the first piece ES. The second piece ZS of each fill area FB and the second piece ZS are formed from polysilicon. In this embodiment, each fill area FB thus has an electrically insulating area which is formed by the first piece ES, and a slightly electrically conductive area which is formed by the second piece ZS. In this embodiment as well, the fill area FB may be produced in many ways. It is also possible to provide in this case for the distances between the drain region D and the substrate surface and from the base area of the well area WB to be the same as or less than the distance of the first pieces ES of the fill areas FB. It is likewise possible to provide for the second pieces ZS to be coincident with the first pieces ES, or to be larger or smaller than the first pieces ES. It is also possible to provide for the second pieces ZS to extend as a complete cohesive layer over the first pieces ES and the drain region D. Furthermore, it is possible for the second pieces ZS to extend to a depth below the surface O.

A third embodiment of the transistor is illustrated in FIG. 4. In this embodiment, the fill areas FB are likewise formed from two pieces. The first pieces ES, as can be seen in the section illustration in FIG. 4, are formed by subareas of the well area WB. These first pieces ES are thus homogenous areas of the well area WB, which extend to the surface O. In this embodiment as well, the fill areas FB are in the form of strips. In this embodiment, it should be noted that the drain region D is embedded in the well area WB and that, as a result of the first pieces ES passing through the fill areas FB, has a structure which is in the form of strips or laminates, with the parallel strips of the drain region D each being connected to one another at the ends. In addition to the first pieces ES, the fill areas FB in this embodiment also have second pieces ZS, which are arranged on the first pieces ES and are formed from polysilicon. Since the fill areas FB, in particular the first pieces ES, are in this embodiment formed by subareas of the well area WB in which the drain region D is completely embedded, the fill areas FB in this embodiment logically extend with a greater depth than the drain region D. Thus, in this embodiment, there is no distance a. In this embodiment, the areas of the drain region D which are in the form of strips are produced by implantation in the well area WB. The third embodiment as shown in FIG. 4 can also be modified in many ways. For example, it is also possible to provide for the second pieces ZS to be completely omitted. It is also possible to provide for the first pieces ES not to be formed completely as far as the surface O and thus for the second pieces ZS which are formed on them to be below the surface O. It is also possible to provide for a third piece, for example an electrically insulating third piece composed of silicon dioxide, to be arranged between the first piece ES and the second piece ZS.

The additional second polysilicon pieces ZS, which are shown in the embodiments in FIG. 3 and FIG. 4, allow a further positive influence to be achieved with respect to the shifting of the threshold voltage of the transistor, by the relatively large diffusion regions of the transistor being effectively interrupted. These polysilicon pieces ZS reduce the grid voltages in the diffusion regions of the transistor. This makes it possible to even more effectively avoid characteristic shifts in certain manufacturing technologies. Furthermore, these polysilicon pieces allow better lithographic precision to be achieved since, effectively, additional polysilicon areas are provided thus making it possible to ensure good lithography by means of a polysilicon density which is as high as possible and is distributed uniformly on the chip.

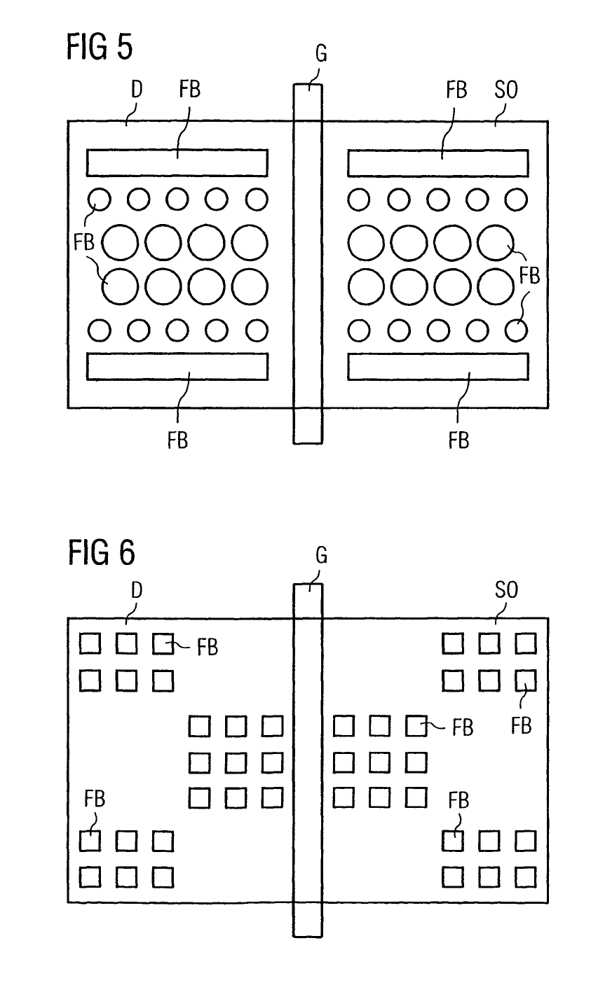

FIG. 5 shows a further embodiment of a transistor. This plan view shows a number of fill areas FB both in the drain region D and in the source diffusion region SO, with the fill areas FB being composed of fill areas FB in the form of strips and solid-cylindrical fill areas FB. Some of the solid-cylindrical fill areas FB have a first diameter which is less than the diameter of second solid-cylindrical fill areas FB. As shown in this fourth embodiment, the fill areas FB which are formed in the diffusion regions D and SO can be produced from a combination of different geometric shapes.

In a further embodiment shown in FIG. 6, the fill areas are quadrilateral pillars. As can be seen from the plan view shown in FIG. 6, the fill areas FB are distributed in the respective diffusion regions D homogeneously, and are arranged with a corresponding concentration density in the corresponding regions of the respective diffusion region D and SO.

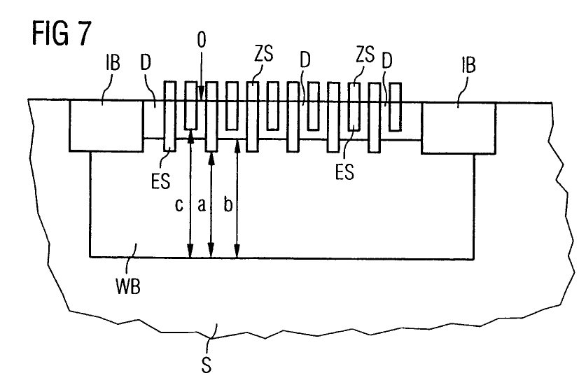

FIG. 7 shows a sixth embodiment, in the form of a further section illustration of a transistor. In this embodiment, the fill areas FB are formed from a first piece ES and a second piece ZS. The fill areas FB have different vertical dimensions. In the section illustration, adjacent first pieces ES of a respective fill area FB have different vertical dimensions, with the first piece ES of a first fill area FB being formed with a depth which is greater than the depth of the drain region D, and this first piece ES being at a distance a from the substrate surface of the base area of the well are WB. A first piece ES, which is adjacent to this in a horizontal direction, of an adjacent further fill area FB is formed with a depth which is less than the depth of the drain region D, and is at a distance c from the substrate surface and the base of the well area WB.

In all of the embodiments, it is possible to provide for the structure or the shape and arrangement of the fill areas to be different in the drain region D to the source region SO. The second pieces ZS on the respective fill area FB are filled with an essentially identical vertical extent. The embodiment of FIG. 7 shows that it is also possible for two fill areas FB in a diffusion region SO and/or D to each have at least one piece which are formed from essentially the same materials, but which have different vertical dimensions. The complete fill areas FB likewise have different vertical dimensions. Each fill area is, however, designed such that its overall vertical extent and its overall vertical length are at least of the same size as the vertical extent of the drain region D and/or of the source region SO.

The transistor may be an MOS (Metal Oxide Semiconductor) or a lateral bipolar transistor. In all of the embodiments, it is also possible to provide for a salicide layer to be arranged on the source region SO and/or on the drain region D, with the structure of the fill areas FB being transferred to this salicide layer. This makes it possible to reduce crystal stresses and thus to improve the characteristics of the transistor, and/or the leakage current problem.

As can be seen in all of the embodiments, there is no need for the invention for the drain regions D and/or source regions SO to be cut through or passed through completely by the fill areas FB, but to have vertical dimensions which are at least as large as the vertical dimensions of the respective diffusion region D and/or SO. In this case, it is possible for the fill areas FB to extend beyond the surface O, away from the substrate.

As shown in all of the embodiments, the fill areas FB, when considered in the vertical direction, do not extend below spacer areas or the gate area of the transistor. When considered in the horizontal direction, the fill areas FB are thus arranged at a distance from the spacer areas or from the gate area of the transistor, as can also be seen in the illustration in FIGS. 1, 5 and 6.

As shown, the fill areas FB are geometrically shaped such that it is possible for the fill areas FB and the source and/or drain regions SO and D of the transistor to engage in one another, or to extend into one another, to prevent a characteristic shift or shift in the characteristic variables of the transistor irrespective of its size, its geometry and its environment on the integrated circuit. Each transistor in an integrated circuit can be designed such that its characteristic variables and its characteristics remain virtually unchanged irrespective of the process technology that is used in each case. A physical effect is prevented which is independent of the physical effect of an ESD event, specifically the shifting of characteristic variables, in particular the shifting of the threshold voltage.

It is therefore intended that the foregoing detailed description be regarded as illustrative rather than limiting, and that it be understood that it is the following claims, including all equivalents, that are intended to define the spirit and scope of this invention. Nor is anything in the foregoing description intended to disavow scope of the invention as claimed or any equivalents thereof.

1. A transistor comprising:
a source and a drain region which are formed in a substrate; and
a plurality of fill areas, each fill area arranged at least partially in the substrate, the fill areas comprising at least one of oxide or nitride, at least one of the source or drain region and the fill areas extending into one another, the fill areas having vertical dimensions which are at least of equal size to vertical dimensions of the at least one of the source or drain region.

2. The transistor as claimed in claim 1, wherein the fill areas pass completely through the at least one of the source or drain region in a vertical direction.

3. The transistor as claimed in claim 1, wherein the fill areas are integral and are substantially homogeneous.

4. The transistor as claimed in claim 1, wherein the fill areas and the at least one of the source or drain region form a substantially planar surface on a surface of the substrate.

5. The transistor as claimed in claim 1, wherein the fill areas extend further from a surface of the substrate than at least one of the source or drain region.

6. The transistor as claimed in claim 1, wherein the fill areas each have first and second pieces which are arranged vertically.

7. The transistor as claimed in claim 6, wherein the first pieces extend into the substrate and the second pieces are arranged coincidentally with respect to the first pieces.

8. The transistor as claimed in claim 1, wherein the fill areas are slightly electrically conductive at least in subareas or are electrically insulating at least in subareas in comparison to the at least one of the source or drain region.

9. The transistor as claimed in claim 1, wherein the at least one of the source or drain region is embedded in a well area which is formed in the substrate, and the fill areas are subareas of the well area.

10. The transistor as claimed in claim 9, wherein the fill areas each have first and second pieces which are arranged vertically, and the second pieces are slightly electrically conductive in comparison to the at least one of the source or drain region.

11. The transistor as claimed in claim 1, wherein the fill areas comprise strips which are arranged substantially parallel to one another and are arranged at right angles to a gate area of the transistor.

12. The transistor as claimed in claim 1, wherein the fill areas comprise at least one of solid cylinders, hollow cylinders, or polygonal pillars.

13. The transistor as claimed in claim 1, wherein the fill areas have at least one of different geometric shapes or vertical dimensions in a diffusion region.

14. The transistor as claimed in claim 1, wherein a salicide layer is formed on at least one of the fill areas or the at least one of the source or drain region.

15. The transistor as claimed in claim 14, wherein a structure of the fill areas is formed in the salicide layer.

16. The transistor as claimed in claim 1, further comprising isolation areas isolating the at least one of the source or drain region from adjacent diffusion regions of adjacent transistors, the at least one of the source or drain region and fill areas disposed between the isolation areas.

17. A transistor comprising:
a source and a drain region, the source and drain regions formed by diffusion regions in a substrate; and
a plurality of fill areas arranged in at least one of the source and drain regions, the fill areas extending into the substrate at least as far as the at least one of the source and drain regions, the fill areas more insulating than the at least one of the source and drain regions.

18. The transistor as claimed in claim 17, wherein the fill areas are substantially planar with a surface of the substrate.

19. The transistor as claimed in claim 17, wherein the fill areas extend further into the substrate than the at least one of the source and drain regions.

20. The transistor as claimed in claim 17, wherein the fill areas comprise first pieces that extend into the substrate and second pieces that extend out of the substrate.

21. The transistor as claimed in claim 20, wherein the first and second pieces are arranged coincidentally.

22. The transistor as claimed in claim 17, further comprising a well area formed in the substrate in which the at least one of the source and drain regions is embedded.

23. The transistor as claimed in claim 22, wherein the fill areas comprise a portion of the well area.

24. The transistor as claimed in claim 22, wherein the fill areas are more insulating than the well area.

25. The transistor as claimed in claim 17, wherein the fill areas comprise strips which are arranged substantially parallel to one another between at least one of adjacent source electrodes and adjacent drain electrodes.

26. The transistor as claimed in claim 17, wherein the fill areas comprise at least one of solid cylinders, hollow cylinders, or polygonal pillars.

27. The transistor as claimed in claim 17, wherein the fill areas have at least one of different geometric shapes or vertical dimensions in the diffusion region forming the at least one of the source and drain regions.

28. The transistor as claimed in claim 17, wherein the fill areas comprise sets of fill areas, the fill areas in each set having substantially the same size and shape and having a different size and shape from the fill areas of other sets.

29. The transistor as claimed in claim 17, wherein the fill areas comprise sets of fill areas, the fill areas in each set having substantially the same size and shape, the fill areas in each set clustered together and separated from the fill areas in other sets.
